(19) United States
(12) Patent Application Publication
(10) Pub. No.: US 2021/0327717 A1
(43) Pub. Date: Oct. 21, 2021

(54) Methods and Apparatus for Integrated Cobalt Disilicide Formation

(71) Applicant: Applied Materials, Inc., Santa Clara, CA (US)

(72) Inventors: Tom Ho Wing Yu, Campbell, CA (US); Nobuyuki Sasaki, Cupertino, CA (US); Kazuya Daito, Milipitas, CA (US)

(73) Assignee: Applied Materials, Inc., Santa Clara, CA (US)

(21) Appl. No.: 16/849,988

(22) Filed: Apr. 15, 2020

(51) Int. Cl. H01L 21/285; H01L 21/02; H01L 21/67; H01L 21/687

(52) U.S. Cl. CPC H01L 21/28518; H01L 21/68707; H01L 21/67167; H01L 21/02068

(57) ABSTRACT

Methods and apparatus for the formation of cobalt disilicide are described. Some embodiments of the disclosure provide in-situ methods of forming cobalt disilicide. The resulting films are smoother and have lower resistance and resistivity than films formed by similar ex-situ methods. Some embodiments of the disclosure provide apparatus for performing the described methods without an air break between processes.

### TECHNICAL FIELD

Embodiments of the disclosure generally relate to methods and apparatus for forming cobalt disilicide (CoSi₂). In particular, embodiments of disclosure relate to methods and apparatus for forming cobalt disilicide without an air break.

### BACKGROUND

For node over node shrinking geometries, to maintain or reduce resistance, it may become critical to deposit thinner cobalt films for cobalt silicide (CoSiₓ) contact and make sure the cobalt does not oxidize.

Current technologies utilize separate processing chambers for cobalt deposition and thermal annealing. The transfer between the chambers, under ambient atmosphere, provides the opportunity for oxidation of the deposited cobalt before the anneal process.

Accordingly, current technologies utilize a TiN capping layer to protect deposited cobalt from oxidation before annealing. However, while the TiN capping layer reduces oxidation, a significant level of oxidation still occurs during the transfer between processing chambers. The additional oxygen content leads to an undesireable increase in the resistivity of the cobalt silicide.

Further, the cobalt silicide formed by the current technologies can take several stoichiometric forms including Co₂Si, CoSi and CoSi₂. Of these, CoSi₂ has preferable properties in many semiconductor manufacturing applications, yet its formation by current technologies is not predominant.

Accordingly, there is a need for methods and apparatus for the formation of cobalt disilicide (CoSi₂).

### SUMMARY

One or more embodiments of the disclosure are directed to a method of forming cobalt disilicide. The method comprises depositing a cobalt layer on a silicon substrate. The cobalt layer is annealed to form a cobalt disilicide layer. There is no air break between depositing and annealing.

Additional embodiments of the disclosure are directed to a multi-chamber processing tool comprising an optional first chamber connected to a central transfer station. The first chamber is configured to preclean a silicon substrate. The central transfer station is maintained under vacuum. A second chamber is connected to the central transfer station and is configured to deposit a cobalt layer on the clean silicon substrate. A third chamber is connected to the central transfer station and is configured to anneal the cobalt layer. A controller is connected to and configured to control the optional first chamber, the second chamber and the third chamber.

Further embodiments of the disclosure are directed to a non-transitory computer readable medium including instructions, that, when executed by a controller of a processing chamber, causes the processing chamber to perform operations of: precleaning a substrate in a first chamber; moving the substrate to a second chamber without an air break; depositing cobalt on the substrate in the second chamber; moving the substrate to a third chamber without an air break; and annealing the substrate to form cobalt disilicide.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a flowchart of a method for forming cobalt disilicide in accordance with one or more embodiment of the disclosure;

FIG. 2 is a schematic diagram of a multi-chamber processing tool in accordance with one or more embodiment of the disclosure; and

FIG. 3 is an XRD spectrum of a samples prepared in accordance with one or more embodiment of the disclosure; and

FIG. 4 is an XRD spectrum of a sample prepared in accordance with one or more embodiment of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon

A “substrate” as used herein, refers to any substrate or material surface formed on a substrate upon which film processing is performed during a fabrication process. In addition to film processing directly on the surface of the substrate itself, in the present disclosure, any of the film processing steps disclosed may also be performed on a layer formed on the substrate as disclosed in more detail below, and the term “substrate surface” is intended to include such layer as the context indicates. Thus for example, where a film/layer or partial film/layer has been deposited onto a substrate surface, the exposed surface of the newly deposited film/layer becomes the substrate surface.

One or more embodiments of the disclosure are directed to methods for forming cobalt disilicide without an air break. Some embodiments advantageously eliminate any risk of cobalt oxidation. Some embodiments advantageously provide for a reduction in the thickness of cobalt necessary to form the cobalt disilicide layer relative to similar processes performed with an air break. This reduction in thickness may enable smaller geometry structures. Some embodiments advantageously provide for a reduction in contact resistance. Some embodiments advantageously eliminate the need for a TiN capping layer after depositing the cobalt.

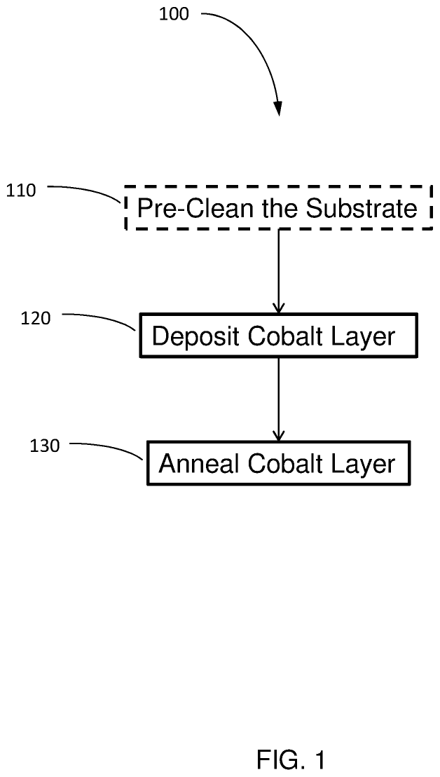

Referring to FIG. 1, one or more embodiments of the disclosure relate to a method 100 for forming cobalt disilicide. The method 100 begins at 110 with an optional pre-clean process. In some embodiments, the surface of the substrate is cleaned. In some embodiments, the cleaning process may remove oxides or other contaminants from the substrate surface. For example, the pre-clean process may remove oxygen, carbon, fluorine or chlorine contaminants from the surface. In some embodiments, the contaminants comprise one or more of silicon oxides, metal oxides, carbon hydrides, or carbon fluorides.

The method 100 continues at 120 by depositing a cobalt layer on the substrate. In some embodiments, the substrate consists essentially of silicon. As used in this regard, a substrate “consisting essentially” of silicon comprises greater than or equal to about 95%, greater than or equal to about 98%, greater than or equal to about 99%, or greater than or equal to about 99.5% of silicon on an atomic basis. The substrate may also be referred to as a silicon substrate. In some embodiments, the substrate comprises polycrystalline silicon. In some embodiments, the substrate comprises amorphous silicon.

The cobalt layer may be deposited by any suitable method. In some embodiments, the cobalt layer is deposited by physical vapor deposition (PVD). In some embodiments, the cobalt layer is deposited by chemical vapor deposition (CVD).

The thickness of cobalt layer may be controlled. In some embodiments, the thickness of the cobalt layer is less than or equal to about 200 Å, less than or equal to about 150 Å, less than or equal to about 125 Å, less than or equal to about 100 Å, less than or equal to about 75 Å, less than or equal to about 50 Å, or less than or equal to about 25 Å. In some embodiments, the thickness of the cobalt layer is in a range of about 20 Å to about 200 Å, in a range of about 25 Å to about 150 Å, in a range of about 40 Å to about 120 Å, or in a range of about 50 Å to about 100 Å. In some embodiments, the cobalt layer is a continuous film. A continuous film, as used herein, is a film of greater than or equal to about 5 Å in average thickness for which less than 5%, 2%, 1% or 0.5% of the surface area of the underlying material is exposed.

After deposition, the cobalt layer is highly susceptible to oxidation. Some embodiments of this disclosure prevent oxidation of the cobalt layer by performing the method “in-situ”. The in-situ method prevents oxidation by having no air break between deposition and annealing.

In some embodiments, the surface of the cobalt layer remains substantially unoxidized before annealing. As used in this regard, a metal surface which is “substantially unoxidized” has less than or equal to about 2%, less than or equal to about 1%, or less than or equal to about 0.5% of oxygen atoms within 5 nm of the surface on an atomic basis. In some embodiments, the substrate with the cobalt layer is subjected to annealing without deposition of a barrier layer (e.g., titanium nitride (TiN)).

After the deposition of the cobalt layer, the cobalt layer is annealed to form a cobalt disilicide layer at anneal process 130. In some embodiments, the anneal process 130 is performed by a rapid thermal processing (RTP) technique (e.g., rapid thermal annealing (RTA)). In some embodiments, annealing the cobalt layer is performed at a temperature greater than or equal to about 600° C., greater than or equal to about 625° C., greater than or equal to about 650° C., or greater than or equal to about 675° C. In some embodiments, annealing the cobalt layer is performed at a temperature in a range of about 550° C. to about 750° C., in a range of about 600° C. to about 700° C., in a range of about 600° C. to about 650° C., in a range of about 650° C. to about 700° C., or in a range of about 625° C. to about 675° C.

The anneal process at 130 is performed under an inert atmosphere. Stated differently, the anneal atmosphere does not react with the cobalt layer or the substrate during the anneal process. In some embodiments, the inert atmosphere comprises one or more of nitrogen (N₂), helium (He) or argon (Ar). In some embodiments, the inert atmosphere consists essentially of N₂, He or Ar. As used in this regard, an atmosphere which consists essentially of a stated gas comprises greater than or equal to about 95%, greater than or equal to about 98%, greater than or equal to about 99%, greater than or equal to about 99.5%, or greater than or equal to about 99.9% of the stated gas on a molar basis. In some embodiments, the inert atmosphere comprises a mixture of nitrogen (N₂) and argon (Ar). In some embodiments, the nitrogen:argon ratio is in the range of about 5:1 to about 1:5, or in the range of about 100:1 to about 1:100.

In some embodiments, the anneal process is performed for a relatively short period of time. In some embodiments, the anneal process is performed for a period of less than or equal to about 10 minutes, less than or equal to about 5 minutes, less than or equal to about 2 minutes, less than or equal to about 1 minute, less than or equal to about 45 seconds, or less than or equal to about 30 seconds. In some embodiments, the anneal process is performed for a period of greater than or equal to about 10 seconds, greater than or equal to about 15 seconds, greater than or equal to about 20 seconds, greater than or equal to about 30 seconds, greater than or equal to about 60 seconds, or greater than or equal to about 120 seconds. In some embodiments, the anneal process is performed for a period in a range of about 15 seconds to about 10 minutes, in a range of about 10 seconds to about 2 minutes, in a range of about 10 seconds to about 1 minute, in a range of about 15 seconds to about 45 seconds, or in a range of about 15 seconds to about 30 seconds.

The anneal process at 130 forms a cobalt disilicide layer. The cobalt disilicide layer has a stoichiometric ratio of cobalt to silicon of about 1:2. In some embodiments, the ratio of cobalt to silicon is in a range of about 1:1.5 to about 1:2.5. In some embodiments, the cobalt disilicide layer may be thicker than the cobalt layer.

In some embodiments, the cobalt disilicide layer has a thickness of greater than or equal to about 10 Å, greater than or equal to about 100 Å, or greater than or equal to about 200 Å. In some embodiments, formation of the cobalt disilicide layer by the in-situ process allows for much smaller thicknesses to be used. In some embodiments, the thickness of the cobalt disilicide layer is sufficient to form a continuous film. In some embodiments, the cobalt disilicide layer has a thickness greater than 10 Å, 15 Å or 20 Å.

As identified above, some embodiments of this disclosure provide cobalt disilicide films with superior properties to those obtained by methods involving an air break (ex-situ methods). In some embodiments, the cobalt disilicide layer is substantially free of oxygen. As used in this regard, “substantially free of oxygen” means that the material has less than or equal to about 5%, less than or equal to about 2%, less than or equal to about 1%, or less than or equal to about 0.5% on an atomic basis per unit volume. In some embodiments, the cobalt disilicide layer has less than or equal to about 0.5%, less than or equal to about 0.3%, less than or equal to about 0.2%, or less than or equal to about 0.1% oxygen on an atomic basis per unit volume.

In some embodiments, the cobalt disilicide layer has a resistance of less than or equal to about 50 Ω/sq, less than or equal to about 20 Ω/sq, less than or equal to about 15 Ω/sq, or less than or equal to about 10 Ω/sq. In some embodiments, the cobalt disilicide layer has a resistivity of less than or equal to about 50 μΩ·cm, less than or equal to about 40 μΩ·cm, less than or equal to about 35 μΩ·cm, less than or equal to about 25 μΩ·cm, or less than or equal to about 20 μΩ·cm.

In some embodiments, the cobalt disilicide films formed by the disclosed process are more uniform. In some embodiments, the cobalt disilicide layer has a resistivity non-uniformity (1σ) of less than or equal to about 10%.

The inventors have surprisingly found that an in-situ process results in a substantially smoother film. In some embodiments, the cobalt disilicide layer is smoother than the cobalt silicide obtained by methods involving an air break (ex-situ methods). In some embodiments, the thickness non-uniformity (1σ) of the cobalt disilicide film resulting from an in-situ process is less than or equal to about 10%. A similar film prepared by an ex-situ process has a thickness non-uniformity (1σ) of greater than or equal to about 20%.

In some embodiments of the method 100, deposition of the cobalt layer and annealing the cobalt layer to form the cobalt disilicide is performed without forming and/or removing a barrier layer. For example, in some embodiments, the substrate with the cobalt layer is subjected to annealing without deposition or removal of a titanium nitride (or similar) barrier layer.

Some embodiments of the disclosure provide multi-chamber processing tools for forming cobalt disilicide. The multi-chamber processing tools of this disclosure may also be referred to as a processing system.

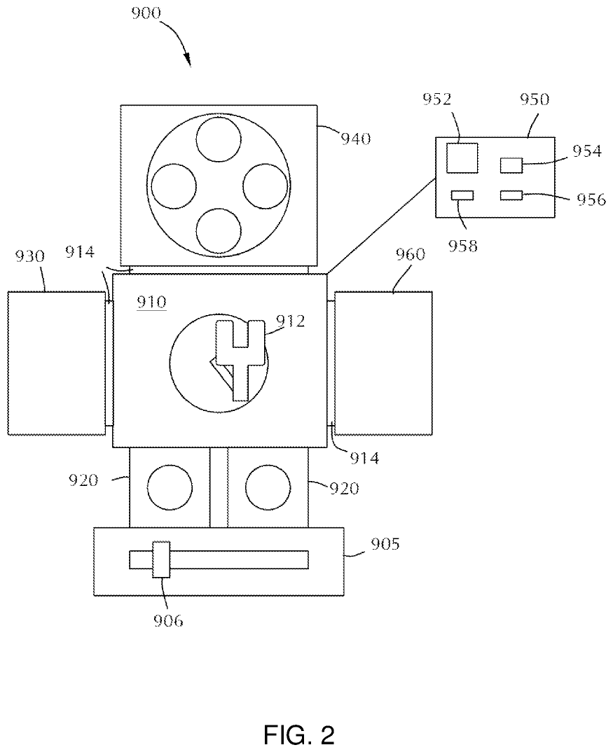

With reference to FIG. 2, additional embodiments of the disclosure are directed to a processing system 900 for executing the methods described herein. FIG. 2 illustrates a system 900 that can be used to process a substrate according to one or more embodiment of the disclosure. The system 900 can be referred to as a cluster tool. In some embodiments, the system 900 includes a central transfer station 910 with a robot 912 therein. In FIG. 2, the robot 912 is illustrated as a single blade robot; however, those skilled in the art will recognize that other robot 912 configurations are within the scope of the disclosure. The robot 912 is configured to move one or more substrate between chambers connected to the central transfer station 910.

As illustrated, at least one buffer chamber 920 is connected to the central transfer station 910. The buffer chamber 920 can include one or more of a heater, a radical source or plasma source. The buffer chamber 920 can be used as a holding area for an individual semiconductor substrate or for a cassette of wafers for processing. The buffer chamber 920 can pre-heat the substrate for processing or can simply be a staging area for the process sequence. In some embodiments, there are two buffer chambers 920 connected to the central transfer station 910.

In the embodiment shown in FIG. 2, the buffer chambers 920 can act as pass through chambers between the factory interface 905 and the central transfer station 910. The factory interface 905 can include one or more robot 906 to move substrate from a cassette to the buffer chamber 920. The robot 912 can then move the substrate from the buffer chamber 920 to other chambers within the system 900.

In some embodiments, a first processing chamber 930 can be connected to the central transfer station 910. The first processing chamber 930 can be configured as pre-clean chamber and may be in fluid communication with one or more reactive gas sources to provide one or more flows of reactive gases to the first processing chamber 930. The substrate can be moved to and from the processing chamber 930 by the robot 912 passing through isolation valve 914.

A second chamber 940 can also be connected to the central transfer station 910. In some embodiments, chamber 940 comprises a deposition chamber and is fluid communication with one or more reactive gas sources to provide flows of reactive gas to the processing chamber 940 to perform the deposition process. The substrate can be moved to and from the processing chamber 940 by robot 912 passing through isolation valve 914.

In some embodiments, a third chamber 960 is connected to the central transfer station 910 and is configured to act as an anneal chamber. The chamber 960 can be configured to perform one or more different anneal processes.

In some embodiments, each of the chambers 930, 940, and 960 are configured to perform different portions of the processing method. For example, chamber 930 may be configured to perform the pre-clean process, chamber 940 may be configured to perform the cobalt deposition process, and chamber 960 may be configured to perform an anneal process. The skilled artisan will recognize that the number and arrangement of individual processing chamber on the tool can be varied and that the embodiment illustrated in FIG. 2 is merely representative of one possible configuration.

In some embodiments, the processing system 900 includes one or more metrology stations. For example metrology stations can be located within buffer chamber 920, within the central transfer station 910 or within any of the individual chambers. The metrology station can be any position within the system 900 that allows the substrate to be measured without exposing the substrate to an oxidizing environment.

At least one controller 950 is coupled to one or more of the central transfer station 910, the buffer chamber 920, and the chambers 930, 940, or 960. In some embodiments, there are more than one controller 950 connected to the individual chambers or stations and a primary control processor is coupled to each of the separate processors to control the system 900. The controller 950 may be one of any form of general-purpose computer processor, microcontroller, microprocessor, etc., that can be used in an industrial setting for controlling various chambers and sub-processors.

The at least one controller 950 can have a processor 952, a memory 954 coupled to the processor 952, input/output devices 956 coupled to the processor 952, and/or support circuits 958 to communication between the different electronic components. The memory 954 can include one or more of transitory memory (e.g., random access memory) and non-transitory memory (e.g., storage).

The memory 954, or computer-readable medium, of the processor may be one or more of readily available memory such as random access memory (RAM), read-only memory (ROM), floppy disk, hard disk, or any other form of digital storage, local or remote. The memory 954 can retain an instruction set that is operable by the processor 952 to control parameters and components of the system 900. The support circuits 958 are coupled to the processor 952 for supporting the processor in a conventional manner. Circuits may include, for example, cache, power supplies, clock circuits, input/output circuitry, subsystems, and the like.

Some embodiments of the disclosure are directed to a non-transitory computer readable medium including instructions, that, when executed by a controller of a processing chamber, causes the processing chamber to perform one or more operations including: precleaning a substrate in a first chamber; moving the substrate to a second chamber without an air break; depositing cobalt on the substrate in the second chamber; moving the substrate to a third chamber without an air break; and/or annealing the substrate to form cobalt disilicide.

Processes may generally be stored in the memory as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

In some embodiments, the controller 950 has one or more configurations to execute individual processes or sub-processes to perform the method. The controller 950 can be connected to and configured to operate intermediate components to perform the functions of the methods. For example, the controller 950 can be connected to and configured to control one or more of gas valves, actuators, motors, slit valves, vacuum control, etc.

The controller 950 of some embodiments has one or more configurations selected from: a configuration to move a substrate on the robot between the plurality of chambers and metrology station; a configuration to load and/or unload substrates from the system; a configuration to pre-clean a substrate; a configuration to deposit a cobalt layer on the substrate; and/or a configuration to anneal the cobalt layer on the substrate.

### EXAMPLES

### Example 1

Four samples were prepared by an embodiment of the disclosure. Each sample was prepared by depositing 40 Å of cobalt on a silicon substrate. The samples were annealed (in-situ) for 30 seconds at 550° C., 600° C., 650° C. and 700° C., respectively.

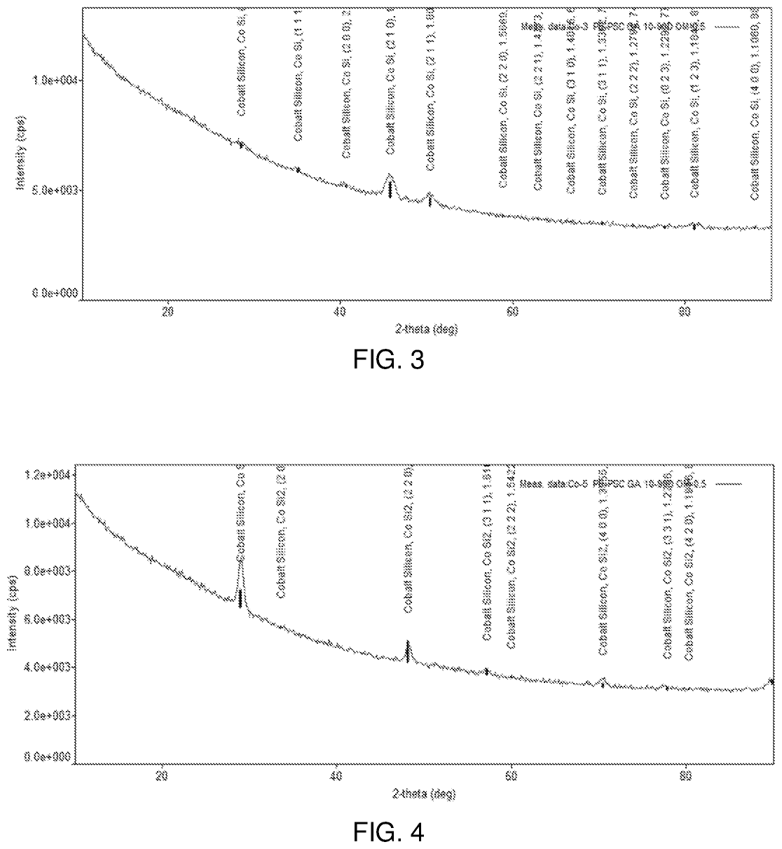

Sample 1 (550° C.) had a sheet resistance of about 700 Ω/sq. Samples 2-4 had a sheet resistance of less than or equal to about 50 Ω/sq. Sample 2 (650° C.) had the lowest sheet resistance of the four samples. More CoSi₂, as compared to other stoichiometric forms, was observed at 650° C. than at 550° C. XRD scans of Samples 1 and 3 are shown in FIGS. 3 and 4.

### Example 2

Three samples were prepared. Each sample was prepared by depositing 120 Å of cobalt on a silicon substrate. Sample A was processed in-situ and annealed at 600° C. for 30 seconds. Sample B had 100 Å of TiN deposited on the cobalt and was processes ex-situ. The sample was annealed at 600° C. for 30 seconds. Sample C was processed in-situ and annealed at 650° C. for 60 seconds. The samples were evaluated for average thickness, CoSi₂ resistance (Ω/sq), resistance non-uniformity (1σ) and resistivity (μΩ·cm). Results are presented in Table 1. The electrical properties of Sample B were unable to be measured due to the TiN capping layer.

TABLE 1

| Sample | A | B | C |
|---|---|---|---|
| CoSi₂ Thk (nm) | 19.4 | 12.5 | 21.8 |
| CoSi₂ Rs (Ω/sq) | 17.6 | — | 9.53 |
| Rs N/U (%1σ) | 5.35 | — | 8.18 |
| CoSi₂ Resistivity | 34.1 | — | 20.8 |
| (μΩ · cm) | | | |

The inventors believe that the above results show that the higher temperature and longer anneal time allowed Sample C to form a thicker CoSi₂ layer than Sample A. Also, the TiN layer of Sample B retarded the formation of CoSi₂.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of forming cobalt disilicide, the method comprising:
depositing a cobalt layer on a silicon substrate; and
annealing the cobalt layer to form a cobalt disilicide layer, wherein there is no air break between depositing and annealing.

2. The method of claim 1, further comprising pre-cleaning the surface of the silicon substrate before deposition of the cobalt layer.

3. The method of claim 1, wherein the surface of the cobalt layer remains substantially unoxidized before annealing.

4. The method of claim 1, wherein the cobalt disilicide layer is substantially free of oxygen.

5. The method of claim 1, wherein a thickness of the cobalt layer is less than or equal to about 150 Δ.

6. The method of claim 5, wherein the thickness is less than or equal to about 25 Δ.

7. The method of claim 5, wherein the cobalt disilicide layer has a thickness of greater than or equal to about 150 Δ.

8. The method of claim 1, wherein annealing the cobalt layer is performed at a temperature greater than or equal to about 600° C.

9. The method of claim 8, wherein the temperature is in a range of about 600° C. to about 700° C.

10. The method of claim 1, wherein annealing the cobalt layer is performed under an argon atmosphere.

11. The method of claim 1, wherein annealing the cobalt layer is performed for a period of greater than or equal to about 30 seconds.

12. The method of claim 11, wherein the period is less than or equal to about 1 minute.

13. The method of claim 1, wherein the cobalt disilicide layer has a resistance of less than or equal to about 20 Ω/sq.

14. The method of claim 13, wherein the resistance is less than or equal to about 10 Ω/sq.

15. The method of claim 1, wherein the cobalt disilicide layer has a resistivity of less than or equal to about 40 μΩ·cm.

16. The method of claim 15, wherein the resistivity is less than or equal to about 20 μΩ·cm.

17. The method of claim 1, wherein the cobalt disilicide layer has a resistivity non-uniformity (1σ) of less than or equal to about 10%.

18. A multi-chamber processing tool comprising:
an optional first chamber connected to a central transfer station and configured to preclean a silicon substrate to form a clean silicon substrate, the central transfer station maintained under vacuum;
a second chamber connected to the central transfer station and configured to deposit a cobalt layer on the clean silicon substrate;
a third chamber connected to the central transfer station and configured to anneal the cobalt layer; and
a controller connected to and configured to control the optional first chamber, the second chamber and the third chamber.

19. The multi-chamber processing tool of claim 18, further comprising a robot within the central transfer station configured to transfer a substrate between the central transfer station, the optional first chamber, the second chamber, and the third chamber.

20. A non-transitory computer readable medium including instructions, that, when executed by a controller of a processing chamber, causes the processing chamber to perform operations of:
precleaning a substrate in a first chamber;
moving the substrate to a second chamber without an air break;
depositing cobalt on the substrate in the second chamber;
moving the substrate to a third chamber without an air break; and
annealing the substrate to form cobalt disilicide.
